(19) United States
(12) Patent Application Publication
(10) Pub. No.: US 2022/0210940 A1
(43) Pub. Date: Jun. 30, 2022

(54) Dual Injection-Molded Metal Substrates

(71) Applicant: Hewlett-Packard Development Company, L.P., Spring, TX (US)

(72) Inventors: Chi Hao Chang, Taipei City (TW); Kuo Chih Huang, Taipei City (TW); Kuan-Ting Wu, Taipei City (TW)

(73) Assignee: Hewlett-Packard Development Company, L.P., Spring, TX (US)

(21) Appl. No.: 17/609,890

(22) PCT Filed: Sep. 6, 2019
(86) PCT No.: PCT/US2019/049894

§ 371 Date: Nov. 9, 2021

(51) Int. Cl. H05K 5/04; C23C 28/00

(52) U.S. Cl. CPC H05K 5/04; C23C 28/34

(57) ABSTRACT

Examples of a dual injection-molded metal substrate have been described. In an example, a dual injection-molded metal substrate includes a magnesium alloy layer injection-molded on a portion of a first surface of an injection-molded aluminum alloy substrate.

### BACKGROUND

Electronic devices, such as keyboards, tablets, laptops, and the like are housed within device covers that have to be aesthetically appealing, while at the same time imparting acceptable mechanical strength, as well as resistance to corrosion. Such device covers may be made of metal substrates. The outer surface of said substrate or device cover, may be suitably treated to provide a patterned or a textured finish to the device.

### BRIEF DESCRIPTION OF DRAWINGS

The following detailed description references the drawings, wherein:

FIG. 1 illustrates a sectional view of a dual injection-molded metal substrate, according to an example of the present disclosure;

FIG. 2 illustrates a sectional view of a dual injection-molded metal substrate with magnesium alloy injection-molded on a portion of the aluminum alloy substrate, according to an example of the present disclosure;

FIG. 3 illustrates a device with a sectional view of a device cover comprising a dual injection-molded metal substrate, according to another example of the present disclosure;

FIG. 4 illustrates a method of forming a device cover comprising a dual injection-molded metal substrate, according to an example of the present disclosure;

FIG. 5 illustrates a method of forming a device cover comprising depositing a treatment layer on at least one chamfered surface, according to an example of the present disclosure.

### DETAILED DESCRIPTION

### Definitions

For convenience, before further description of the present disclosure, certain terms employed in the specification, and examples are described here. These definitions should be read in the light of the remainder of the present disclosure. The terms used herein have the meanings recognized and known to those of skill in the art, however, for convenience and completeness, particular terms and their meanings are set forth below.

The articles “a”, “an”, and “the” are used to refer to one or to more than one (i.e., to at least one) of the grammatical object of the article.

The term “about” when referring to a numerical value is intended to encompass the values resulting from variations that can occur during the normal course of performing a method. Such variations are usually within plus or minus 5 to 10 percent of the stated numerical value.

The term “alloy” refers to the class of materials that may be referred to as a solid solution of metals. The aluminum alloy in the present disclosure is selected from AL5005, A380, AL5050, AL5052, AL5154, AL5252, AL6061, AL6063, AL6151, AL6162, AL6205, AL7072, AL7075, AL7475, AL1100, AL575, A413, ADC12, or combinations thereof. The magnesium alloy in the present disclosure is selected from AZ31B, AZ91D, AZ61, AZ60, AZ80, AM60, LZ91, LZ141, LZ142, ALZ691, or combinations thereof.

The term “molded”, and variations, such as “molding”, used herein refer to injection-molding of alloy.

The term “injection-molding”, used herein refers to the technique for manufacturing parts by injecting molten material into a mold. Injection molding may be carried out by a process, such as thixo-molding or die-casting at a temperature of from about 450° C. to about 850° C.

The term “substrate”, used herein refers to a frame containing aluminum alloy that is used to obtain the device cover of the present disclosure. The substrate can be obtained by injection-molding techniques, such as thixo-molding or die-casting.

The term “chemico-mechanically stable”, used herein refers to substrates having high tensile strength and/or high resistance to breakage and/or high corrosion resistance.

The term “high gloss edges”, used herein refers to chamfered surfaces (in particular, the edges) of the substrate that reveal shiny edges.

Device covers, or body of electronic devices, are made of metal enclosures that have strength, resistance towards corrosion, in particular at chamfered portions, and aesthetic appeal. Metal alloys, such as magnesium alloy substrates are prone to corrosion and, also suffer from poor tensile strength. However, their low density and compatibility with associated techniques, such as spray coating and/or passivation treatment, make such alloys attractive choices for enhancing both aesthetic appeal and resistance towards corrosion of substrates.

Enhancement of aesthetics, for example, by providing high loss finish, is considered desirable for electronic encasement. However, the employment of metal substrates, such as magnesium alloys, is yields poorer finish. Hence, a lustrous over-coat is provided on such metal substrates for ensuring an acceptable finish.

However, in case chamfering is carried out on portions of the metal substrate, for example, to create rounded edges of keyboards, laptops, tablets, mobile phones and the like, surface corrosion tends to occur on chamfered portions of magnesium alloy materials leading to inferior gloss finish. Aluminum alloys, on the other hand, can offer better durability against corrosion resistance, especially upon passivation. However, a purely aluminum alloy-based casing would result in increase in weight and also aluminum alloys offer relatively poor compatibility with known processing techniques.

The present subject matter describes examples of injection-molding a magnesium alloy on a portion of a first surface of an injection-molded aluminum alloy substrate. The aluminum alloy may be selected from AL5005, AL5050, A380, AL5052, AL5154, AL5252, AL6061, AL6063, AL6151, AL6162, AL6205, AL7072, AL7075, AL7475, AL1100, AL575, A413, ADC12, or combinations thereof. The dual injection-molded metal substrate results in an overall high tensile strength and an improved corrosion resistance at the chamfered portion and as a consequence, enhanced durability. In an example, the tensile strength of the alloy, i.e., injection-molded aluminum alloy substrate may be in a range of from about 50 MPa to about 700 MPa as measured by American Society for Testing and Materials (ASTM) D790. This is found to be an enhancement from the magnesium alloy having a tensile strength of from about 30 to about 400 MPa. The magnesium alloy may be selected from AZ31B, AZ91D, AZ61. AZ60, AZ80, AM60, LZ91, LZ141, LZ142, ALZ691, or combinations thereof. The injection-molding may be carried out by thixo-molding or die-casting at a temperature of from about 350° C. to about 850° C. The aluminum alloy substrate may be pre-fabricated into a suitable format or mold by injection-molding. The injection-molding of magnesium alloy is carried out on the aluminum alloy mold. The injection-molded magnesium alloy may have a thickness of from about 0.3 mm to about 2.0 mm. The magnesium alloy having a thickness beyond 2.0 mm may lead to substrates that are unsuitable for forming enclosures of electronic devices owing to excess weight. On the other hand, a magnesium alloy having a thickness lower than 0.3 mm may be weak and chemico-mechanically unstable.

The magnesium alloy may be injection-molded on a first surface of the injection-molded aluminum alloy substrate, such that a portion or the whole of the surface or the interface between the first and second surface may be in contact with the magnesium alloy.

Further, the injection-molded magnesium alloy is readily adaptable to techniques, such as electrophoretic deposition or spray coating, thus allowing relatively easy deposition of a finishing layer that can provide enhancement of aesthetic appeal of the thus obtained electronic device covers. The finishing layer may have a thickness of from about 15.0 μm to about 65.0 μm.

Further, the injection-molded magnesium alloy is readily adaptable to techniques, such as passivation, thus allowing relatively easy formation of a passivation layer that can provide corrosion resistance to the thus obtained electronic device covers. The passivation layer may have a thickness of from about 1.0 μm to about 15.0 μm.

Further, chamfering of the dual injection-molded substrate may provide high gloss finish at the edges. Chamfering may be carried out by a CNC diamond cutting machine or a laser engraving machine. In an example, the chamfering may be carried out with a laser engraving machine having a Nd:YAG laser under a laser power of from about 20 to about 200 W and an engraving speed of from about 100 to about 500 mm/minute. In another example, the laser etching may be carried out under a laser power in a range of from about 50 to about 150 W and an engraving speed of from about 120 to about 480 mm/minute. In another example, the laser etching may be carried out at a laser power of about 100 W and an engraving speed of about 450 mm/minute. In another example, the chamfering may be carried out with a CNC diamond cutting machine at speed of from about 5000 to about 90000 rpm for a period in a range of from about 3 to about 8 minutes. In another example, the chamfering may be carried out with a CNC diamond cutting machine at speed of from about 6000 to about 80000 rpm. Chamfering results in an etching that reveals the underlying shiny/pristine aluminum alloy substrate surface.

In some examples, chamfering may be carried out on a portion of the substrate. The chamfering may be carried out at portions such as clickpad, fingerprint scanner, edge, or sidewall. In an example, the chamfering is carried out at the edge. In another example, the chamfering is carried out at the fingerprint scanner.

Further, chamfering of the substrate, with or without passivation and/or finishing layers, may provide high gloss finish at the edges. In an example, the chamfering is carried out on a portion of the finished substrate.

The aesthetic quality of thus obtained device covers may be quantified by measuring a gloss value. In an example, the gloss value of the chamfered portion may be in a range of from about 85 to about 99 units as measured by American Society for Testing and Materials (ASTM) D523 at a viewing angle of about 20°. This is found to be an enhancement from the unchamfered portion that may result in a gloss value in the range of from about 60 to about 75 units as measured by American Society for Testing and Materials (ASTM) D523 at a viewing angle of about 20°. In another example, the gloss value of the chamfered surface decoration layer may be in a range of from about 87 to about 95 units as measured by ASTM D523 at a viewing angle of about 20°. Overall, the methodology of dual injection-molding a magnesium alloy on an injection-molded aluminum substrate and the further forming and deposition of passivation and finishing layers, respectively on the dual injection-molded metal substrate, according to the present subject matter, is simple, less time and resource consuming, and cost advantageous. Further, the device covers thus obtained are aesthetically appealing, while also being chemico-mechanically stable.

The following detailed description refers to the accompanying drawings. Wherever possible, the same reference numbers are used in the drawings and the following description to refer to the same or similar parts. While several examples are described in the description, modifications, adaptations, and other implementations are possible. Accordingly, the following detailed description does not limit the disclosed examples. Instead, the proper scope of the disclosed examples may be defined by the appended claims.

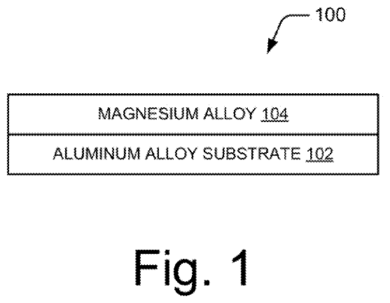

FIG. 1 illustrates a sectional view of dual injection-molded metal substrate 100, according to an example of the present disclosure. The dual injection-molded metal substrate 100 includes an injection-molded aluminum alloy substrate 102 and a magnesium alloy 104 injection-molded on a portion of a first surface of the aluminum alloy substrate 102.

In an example, the aluminum alloy substrate is obtained by injection-molding at a temperature of from about 450° C. to about 850° C. In another example, the aluminum alloy substrate is obtained by injection-molding at a temperature of from about 500° C. to about 800° C. In another example, the aluminum alloy substrate is obtained by injection-molding at a temperature of from about 520° C. to about 750° C.

In an example, the aluminum alloy substrate 102 may be of a thickness in a range of from about 0.3 to 2.0 mm. In another example, the aluminum alloy substrate 102 may be of a thickness in a range of from about 0.5 to 1.8 mm. In another example, the aluminum alloy substrate 102 may be of a thickness of 0.7 mm.

In an example, the magnesium alloy is injection-molded onto the aluminum alloy substrate at a temperature of from about 350° C. to about 850° C. In another example, the magnesium alloy is injection-molded onto the aluminum alloy substrate at a temperature of from about 400° C. to about 750° C. In another example, the magnesium alloy is injection-molded onto the aluminum alloy substrate at a temperature of from about 450° C. to about 700° C.

In an example, the aluminum alloy substrate 102 may be made from an injection-molding process selected from thixo-molding or die-casting.

In an example, the aluminum alloy may be selected from AL5005, AL5050, A380, AL5052, AL5154, AL5252, AL6061, AL6063, AL6151, AL6162, AL6205, AL7072, AL7075, AL7475, AL1100, AL575, A413, ADC12, or combinations thereof. In an example, the alloy 102 can be AL5005. In another example, the alloy 102 may be made up of A380.

In an example, the magnesium alloy may be selected from AZ31B, AZ91D, AZ61, AZ60, AZ80, AM60, LZ91, LZ141, LZ142, ALZ691, or combinations thereof. In an example, the magnesium alloy 104 may be AZ31B. In another example, the alloy 104 may be made up of AZ91D.

The presence of aluminum alloy substrate 102 in the dual injection-molded metal substrate 100 renders it chemico-mechanically stable. In an example, the die casted magnesium alloy AZ91D provides a tensile strength of about 230 MPa, whereas a die casted aluminum alloy A380 provides a tensile strength of about 324 MPa. The dual injection-molded metal substrate 100, may as a consequence have enhanced tensile strength owing to the presence of the aluminum alloy substrate 102.

In an example, the presence of the injection-molded magnesium alloy 104 on a portion of a first surface of the aluminum alloy substrate 102, may lead to easy processing, lowering of overall weight of the dual injection-molded metal substrate 100.

As described above, the dual injection-molded metal substrate 100 includes the magnesium alloy 104 injection-molded on a portion of the first surface of the aluminum alloy substrate 102. The alloy may be molded on a portion of the first surface of the aluminum alloy substrate, such that a section or the whole of the surface may be in contact with the alloy.

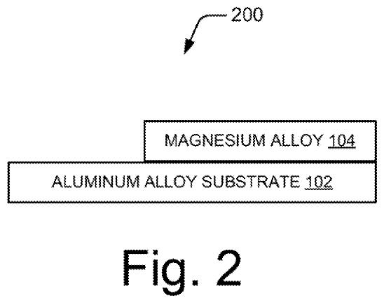

FIG. 2 illustrates a sectional view of dual injection-molded metal substrate 200, according to an example of the present disclosure. As shown in FIG. 2, the dual injection-molded metal substrate 100 includes an injection-molded aluminum alloy substrate 102 and a magnesium alloy 104 injection-molded on a section of a first surface of the aluminum alloy substrate 102.

In an example, the magnesium alloy layer 104 on a portion of a first surface of the aluminum alloy substrate 102 provides a patterned finish. In an example, the magnesium alloy 104 may be injection-molded onto at least 10% of the surface of the aluminum alloy substrate. In another example, the magnesium alloy 104 may be injection-molded onto at least 20% of the surface of the aluminum alloy substrate. In another example, the magnesium alloy 104 may be injection-molded onto at least 45% of the surface of the aluminum alloy substrate. In another example, the magnesium alloy 104 may be injection-molded onto at least 65% of the surface of the aluminum alloy substrate.

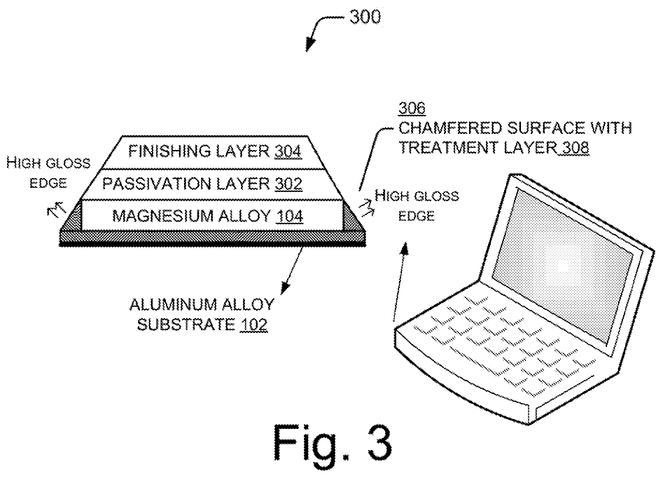

The surface of the dual injection molded substrate as shown in FIG. 1 or 2 may further deposited with a passivation layer and a finishing layer. Further, the chamfering may be carried out at portions such as edge walls, followed by deposition of a treatment layer. Mentioned aspects are described by way of FIG. 3.

FIG. 3 illustrates an electronic device alongside a sectional view 300 of a device cover for the electronic device. The device cover for an electronic device comprises a magnesium alloy 104 that is injection-molded on a surface of the injection-molded aluminum alloy substrate 102. Further a passivation layer 302 is formed on the substrate. The passivation layer 302 may be formed on a portion or on the entire surface of substrate. In an example, the passivation layer 302 may be formed on the sections containing magnesium alloy. In another example, the passivation layer 302 may be formed on the entire substrate, including both aluminum and magnesium sections. In an example, the passivation layer may have a thickness in a range of from about 1.0 μm to about 15.0 μm. In another example, the passivation layer may have a thickness in a range of from about 1.5 μm to about 3.0 μm.

In an example, the passivation layer 302 may be formed by a process of oxidation or coating. In an example, the passivation layer 302 may be formed by micro-arc oxidation carried out at a voltage of from about 150 V to about 550 V at a temperature of from about 10° C. to about 45° C. for a period of from about 2 minutes to about 25 minutes. In another example, the passivation layer 302 may be formed by micro-arc oxidation carried out at a voltage of from about 250 V to about 450 V at a temperature of from about 12° C. to about 42° C. for a period of from about 5 minutes to about 22 minutes. In an example, the passivation layer 302 obtained by micro-arc oxidation has a thickness of from about 2 μm to about 15 μm. In another example, the passivation layer 302 obtained by micro-arc oxidation has a thickness of from about 3 μm to about 12 μm. In another example, the passivation layer 302 obtained by micro-arc oxidation has a thickness of from about 3 μm to about 7 μm.

In an example, the micro-arc oxidation may be carried out in the presence of at least one chemical selected from sodium silicate, metal phosphates, potassium fluoride, potassium hydroxide, sodium hydroxide, fluorozirconates, sodium hexametaphosphate, sodium fluoride, ferric ammonium oxalate, phosphoric acid salt, graphite powder, silicon dioxide powder, aluminum oxide powder, and combinations thereof. In an example, the at least one chemical may be sodium silicate. In another example, the at least one chemical may be potassium fluoride. In an example, the chemical may be employed at a dosage of from about 0.05% to about 15% in the presence of water at a pH of from about 9 to about 13. In another example, the chemical may be employed at a dosage of from about 0.1% to about 12% in the presence of water at a pH of from about 9.0 to about 12.5. In another example, the chemical may be employed at a dosage of from about 3.0% to about 9.0% in the presence of water at a pH of from about 9.0 to about 12.5.

In an example, the passivation layer 302 may be formed by a process of dip coating for a period of from about 30 seconds to about 180 seconds. In an example, the passivation layer 302 may be formed by a process of dip coating for a period of from about 30 seconds to about 60 seconds. In an example, the passivation layer 302 obtained by dip-coating may have a thickness of from about 1 μm to about 5 μm. In another example, the passivation layer 302 obtained by dip-coating may have a thickness of from about 1.5 μm to about 3.0 μm.

In an example, the dip coating may be carried out in the presence of at least one salt of manganese, molybdates, vanadate, phosphate, chromate, stannate, and combinations thereof. In an example, the at least one salt may be manganese. In an example, the salt is dispersed in the form of an aqueous solution having a concentration of from about 3% to about 15% based on total weight. In an example, the salt is dispersed in the form of an aqueous solution having a concentration of from about 5% to about 12% based on total weight.

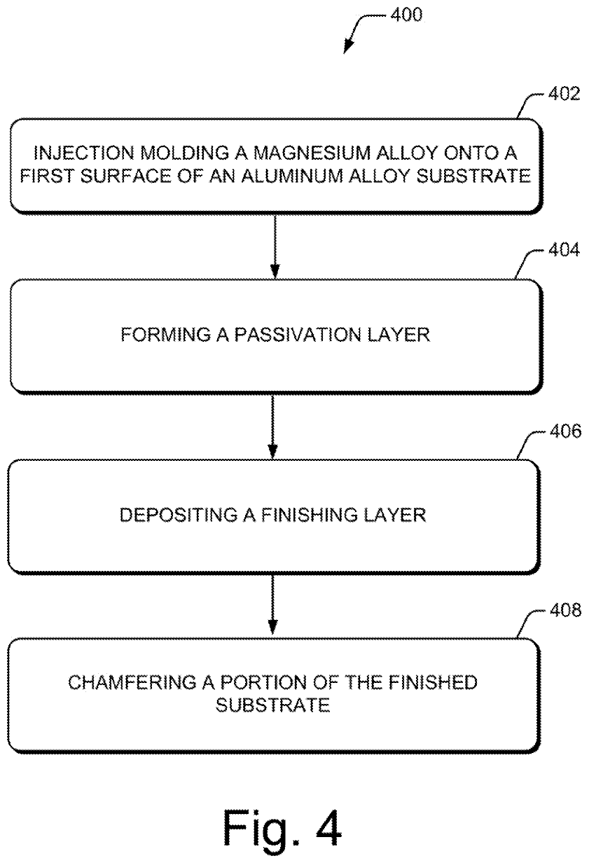

As shown in FIG. 3, the device cover 300 comprises a finishing layer 304 which may be deposited on the passivation layer 302, according to an example of the present disclosure. In an example, the passivation layer may have a thickness of from about 1.0 μm to about 15.0 μm and the finishing layer may have a thickness in a range of from about 15.0 μm to about 65.0 μm. In another example, the finishing layer may have a thickness in a range of from about 30.0 μm to about 60.0 μm. Forming a passivation layer 302 may be carried out by oxidation or coating. Further details of the same have been described herein below in FIG. 4.

As shown in FIG. 3, the device cover 300 comprises chamfered edges 306. In an example, the chamfered surface 306 may reveal an enhanced gloss value of from about 85 to about 99 units as measured by American Society for Testing and Materials (ASTM) D523 at a viewing angle of about 20°. In an example, the chamfered surface 306 may reveal a gloss value of from about 87 to about 97 units. In another example, the chamfered surface 306 may reveal to a gloss value of about 95 units. As mentioned above, chamfering results in an etching that reveals the underlying shiny/pristine aluminum alloy substrate surface which is glossy. In an example, the chamfering may be carried out at portions such as clickpad, fingerprint scanner, edge, or sidewall.

According to an example of the present disclosure, the device cover 300 as shown in FIG. 3, comprises chamfered edges 306 with a treatment layer 308, according to an example of the present disclosure. In an example, the treatment layer 308 may be deposited onto at least one chamfered surface 306 by a process selected from electrophoretic deposition or anodization.

As shown in FIG. 3, the device cover 300 comprising dual injection-molded metal substrate may be employed for electronic devices, such as keyboards, tablets, mobile phones, smartwatches, laptops, and the like. In an example, the device cover 300 may be used as body or frame for keyboards.

Further, details of a method 400 of forming an electronic device cover, are described with reference to FIG. 4. The magnesium alloy 104 may be injection-molded onto the injection-molded aluminum alloy substrate 102. Injection molding 402 may be carried out at a temperature of from about 350° C. to about 850° C. In an example, the injection-molding may be carried out at a temperature of from about 400° C. to about 800° C. In another example, the injection-molding may be carried out at a temperature of from about 450° C. to about 750° C. In another example, the injection-molding may be carried out at a temperature of from about 500° C. to about 700° C.

As shown in FIG. 4, a magnesium alloy 104 can be molded onto a portion of a first surface of an aluminum alloy substrate 102. In an example, the magnesium alloy 104 may be thixomolded on the aluminum alloy substrate 102. In another example, the magnesium alloy 104 may be die-casted on the aluminum alloy substrate 102.

The injection-molding 402 may be carried out on a section or the whole surface of the aluminum alloy substrate. Also, the magnesium alloy may be injection-molded onto more than one surface of the aluminum alloy substrate 102. In an example, the magnesium alloy 104 may be injection-molded onto two surfaces of the aluminum alloy substrate 102. In another example, the magnesium alloy 104 may be injection-molded wholly on the first surface and on a portion of the second surface of the aluminum alloy substrate 102. In case of the magnesium alloy being injection-molded on a section of the surface, the magnesium alloy may be injection-molded onto at least 10% of a surface of the aluminum alloy substrate 102. In case of the magnesium alloy being injection-molded on a section of the surface, the magnesium alloy may be injection-molded onto at least 20% of a surface of the aluminum alloy substrate 102. In case of the magnesium alloy being injection-molded on a section of the surface, the magnesium alloy may be injection-molded onto at least 65% of a surface of the aluminum alloy substrate 102.

In an example, the injection-molding 402 may be carried out by combining the magnesium alloy selected from AZ31B. AZ91D, AZ61, AZ60, AZ80. AM60. LZ91, LZ141, LZ142. ALZ691, or combinations thereof. The mixture obtained from the aforementioned combination may be poured into the aluminum alloy substrate mold at an elevated temperature of from about 350° C. to about 850° C. The molten alloy in the mold may be allowed to cool and solidify. The solidified material may be cleaned, dried, washed, polished, degreased, and activated. The cleaning and washing may be performed using a buffer solution, which may help in removing foreign particles, if any, present on the surface of the solidified material. Further, the solidified material may be chemically polished using abrasives to remove irregularities that may be present on the surface of the solidified material. The solidified material may also be degreased through ultrasonic degreasing methods to remove impurities, such as fat, grease, or oil from the surface of the solidified material. Further, the solidified material may also be activated through acid treatment for removing the natural oxide layer, if any, present on the surface of the solidified material.

The alloy 104 may be of a thickness of from about 0.3 mm to about 2.0 mm. In an example, the alloy 104 may have a thickness of from about 0.4 mm to about 1.9 mm. In another example, the alloy 104 may have a thickness of from about 0.5 mm to about 1.8 mm. In another example, the alloy 104 may have a thickness of about 0.7 mm.

FIG. 4 also illustrates a method of forming an electronic device cover 400, wherein the enclosure comprises a passivation layer. Forming a passivation layer by a passivation process 404, may be carried out by oxidation or coating to obtain the passivation layer 302. In an example, the passivation layer 302 may be formed by passivation process 404. In an example, the passivation process 404 may be carried out by micro-arc oxidation carried out at a voltage of from about 150 V to about 550 V at a temperature of from about 10° C. to about 45° C. for a period of from about 2 minutes to about 25 minutes. In another example, the passivation process 404 may be carried out by micro-arc oxidation carried out at a voltage of from about 250 V to about 450 V at a temperature of from about 12° C. to about 42° C. for a period of from about 5 minutes to about 22 minutes. In an example, the passivation process 404 carried out by micro-arc oxidation may form a passivation layer 302 having a thickness of from about 2 μm to about 15 μm. In another example, the passivation process 404 carried out by micro-arc oxidation may form a passivation layer 302 having a thickness of from about 3 μm to about 12 μm. In another example, the passivation process 404 carried out by micro-arc oxidation may form a passivation layer 302 having thickness of from about 3 μm to about 7 μm.

In an example, the passivation process 404 carried out by micro-arc oxidation may be carried out in the presence of at least one chemical selected from sodium silicate, metal phosphates, potassium fluoride, potassium hydroxide, sodium hydroxide, fluorozirconates, sodium hexametaphosphate, sodium fluoride, ferric ammonium oxalate, phosphoric acid salt, graphite powder, silicon dioxide powder, aluminum oxide powder, and combinations thereof. In an example, the chemical may be employed at a dosage of from about 0.05% to about 15% in the presence of water at a pH of from about 9 to about 13. In another example, the chemical may be employed at a dosage of from about 0.1% to about 12% in the presence of water at a pH of from about 9.0 to about 12.0.

In an example, forming a passivation layer by the passivation process 404 may be carried out by a process of dip coating for a period of from about 30 seconds to about 180 seconds. In an example, the passivation process 404 may be carried out by a process of dip coating for a period of from about 30 seconds to about 180 seconds. In an example, the passivation process 404 may be carried out by dip coating may have a thickness of from about 1 μm to about 5 μm. In another example, the passivation process 404 may be carried out by dip coating may have a thickness of from about 1.5 μm to about 3.0 μm.

In an example, the passivation process 404 may be carried out by dip coating may be carried out in the presence of at least one salt of manganese, molybdates, vanadate, phosphate, chromate, stannate, and combinations thereof. In an example, the at least one salt may be manganese. In an example, the salt may be dispersed in the form of an aqueous solution having a concentration of from about 3% to about 15% based on total weight. In an example, the salt may be dispersed in the form of an aqueous solution having a concentration of from about 5% to about 12% based on total weight.

The FIG. 4 as show above, illustrates a method of forming an electronic device cover 400, wherein the enclosure comprises a depositing process 406 for obtaining a finishing layer. The finishing layer 304 may be deposited onto the passivation layer 302. In an example, the depositing process may be carried out by electrophoretic deposition or spray coating.

In an example, depositing process 406 may result in a finishing layer 304 having a thickness in a range of from about 15.0 μm to about 65.0 μm. In another example, depositing process 406 may result in a finishing layer having a thickness in a range of from about 30.0 μm to about 60.0 μm. In another example, depositing process 406 may result in a finishing layer having a thickness in a range of from about 35.0 μm to about 55.0 μm. In another example, depositing process 406 may result in a finishing layer having a thickness of about 44.0 μm.

The depositing process 406, carried out by spray coating may be carried out in a manner, whereby the finishing layer 304 thus formed may comprise multiple layers, such as primer, base coat, and top coat. In an example, the spray-coated finishing layer 304 comprises sequentially deposited coats of primer having a thickness of from about 5.0 μm to about 20.0 μm, followed by base coat having a thickness of from about 10.0 μm to about 20.0 μm, followed by top coat having a thickness of from about 10.0 μm to about 25.0 μm.

The passivation layer 302 may be cleaned, dried, degreased and washed prior to deposition of the finishing layer 304. The finishing layer 304 may comprise primer, either alone or in combination with one or more other layers. The primer may also be applied as single or multiple coats to achieve the desired thickness and finish. In an example, the primer may have a thickness of from about 5.0 μm to about 20.0 μm. In another example, the primer may have a thickness of from about 8.0 μm to about 18.0 μm. In another example, the primer may have a thickness of about 12.0 μm. In an example, the primer may be deposited on the alloy injection-molded aluminum alloy substrate by spray coating polyurethanes followed by heat treatment at a temperature of from about 60° C. to about 80° C. for a period in a range of from about 15 to about 40 minutes. In another example, the primer may be deposited by spray coating polyurethane followed by heat treatment at a temperature of from about 62° C. to about 78° C. for a period in a range of from about 18 to about 38 minutes. In another example, the primer may be deposited by spray coating thermoplastics, such as polyurethanes followed by heat treatment at a temperature of about 70° C. for a period of about 25 minutes.

The finishing layer 304 may comprise a base coat, in combination with one or more other layers. The base coat may also be applied as single or multiple coats to achieve the desired thickness and finish. In an example, the base coat may have a thickness of from about 10.0 μm to about 20.0 μm. In another example, the base coat may have a thickness of from about 12.0 μm to about 18.0 μm. In another example, the base coat may have a thickness of about 15.0 μm. In an example, the base coat may be a polyurethane containing pigments selected from carbon black, titanium dioxide, clay, mica, talc, barium sulfate, calcium carbonate, aluminum powder, plastic bead, dyes, and combinations thereof. In an example, the spray-coated base coat comprises polyurethane containing carbon black. In another example, the spray-coated base coat comprises polyurethane containing titanium dioxide. In another example, the spray-coated base coat comprises polyurethane containing clay.

In another example, the base coat deposited by spray coating may be followed by heat treatment at a temperature of from about 60° C. to about 80° C. for a period in a range of from about 15 to about 40 minutes. In another example, the base coat deposited by spray coating may be followed by heat treatment at a temperature of from about 62° C. to about 78° C. for a period in a range of from about 18 to about 38 minutes. In another example, the base coat deposited by spray coating may be followed by heat treatment at a temperature of about 70° C. for a period of about 25 minutes.

The finishing layer 304 may comprise top coat, in combination with one or more other layers. The top coat may also be applied as single or multiple coats to achieve the desired thickness and finish. In an example, the top coat may have a thickness of from about 10.0 μm to about 25.0 μm. In another example, the top coat may have a thickness of from about 12.0 μm to about 22.0 μm. In another example, the top coat may have a thickness of about 17.0 μm. In an example, the top coat may be made of polyacrylic acid, polyurethane, urethane acrylates, acrylic acrylates, epoxy acrylates, or combinations thereof. In an example, the top coat is made of polyacrylic acid. In another example, the top coat may be made of polyurethane. In another example, the top coat may be made of urethane acrylates.

In an example, the top coat deposited by spray coating may be followed by UV treatment in a range of from about 700 mJ/cm² to about 1200 mJ/cm² for a period in a range of from about 10 seconds to about 30 seconds. In another example, the top coat deposited by spray coating may be followed by UV treatment in a range of from about 800 mJ/cm² to about 1100 mJ/cm² for a period in a range of from about 15 seconds to about 25 seconds. In another example, the top coat deposited by spray coating may be followed by UV treatment of about 950 mJ/cm² for a period of about 20 seconds.

In another example, the top coat deposited by spray coating a polyurethane may be followed by heat treatment at a temperature of from about 60° C. to about 80° C. for period in a range of from about 15 to about 40 minutes. In another example, the base coat deposited by spray coating may be followed by heat treatment at a temperature of from about 62° C. to about 78° C. for a period in a range of from about 18 to about 38 minutes. In another example, the base coat deposited by spray coating may be followed by heat treatment at a temperature of about 70° C. for a period of about 25 minutes.

The depositing process 406, may be carried out by electrophoretic deposition. In an example, an electrophoretic deposition may be carried out subsequent to the formation of the passivation layer to introduce colors and to provide aesthetically improved finish prior to chamfering. In an example, the electrophoretic deposition may result in deposition of a finishing layer 304 having a thickness of from about 15.0 μm to about 40.0 μm. In another example, the electrophoretically deposited finishing layer 304 may have a thickness of from about 17.0 μm to about 38.0 μm. In another example, the electrophoretically deposited finishing layer may have a thickness of from about 20.0 μm to about 35.0 μm. In another example, the electrophoretically deposited finishing layer may have a thickness of about 20 μm.

The thickness of the finishing layer achieved may be directly related to the potential applied and time for the electrophoretic deposition. In an example, the electrophoretic deposition may be carried out by applying a potential in the range of from about 25 to about 150 V for a period in a range of from about 25 to about 120 seconds. In another example, the electrophoretic deposition may be carried out by applying a potential in the range of from about 40 to about 130 V for a period in a range of from about 60 to about 120 seconds. In another example, the electrophoretic deposition may be carried out by applying a potential of about 100 V for a period of about 80 seconds.

The treatment layer 308 deposited by electrophoretic deposition may comprise at least one polymer selected from polyacrylic polymer, polyacrylamide-acrylic copolymer, epoxy-containing polymer, or blends thereof. In an example, the at least one polymer is polyacrylic polymer. Further, the treatment layer 308 deposited by electrophoretic deposition may comprise at least one dye selected from alexa fluor 594, texas red, pacific blue, pacific orange, quinoline yellow, pigment red 188 MF, or pigment yellow 191. In an example, treatment layer 308 may have a red color imparted by alexa fluor 594. In another example, the treatment layer 308, may have a blue color imparted by pacific blue. In an example, the electrophoretic deposition may be carried out in a manner such that a chamfered portion may have one color, whereas a second chamfered portion may have a different color. In an example, the sidewall portion may have red color, whereas the fingerprint scanner portion may have yellow color.

As shown in FIG. 4, the method of forming electronic device cover 400, comprises chamfering a portion of the finished substrate 408. In an example, the chamfering 408 may be carried out at portions such as edges, sidewall, fingerprint scanner, clickpad, among others.

As shown in FIG. 4, the method of forming an electronic device cover 400 comprises chamfering a portion of the finished substrate to obtain chamfered surface 306. In an example, the chamfering 408 may reveal an enhanced gloss value of from about 85 to about 99 units as measured by American Society for Testing and Materials (ASTM) D523 at a viewing angle of about 20. In an example, the chamfering 408 may reveal a gloss value of from about 87 to about 97 units. In another example, the chamfering 408 may reveal to a gloss value of about 95 units.

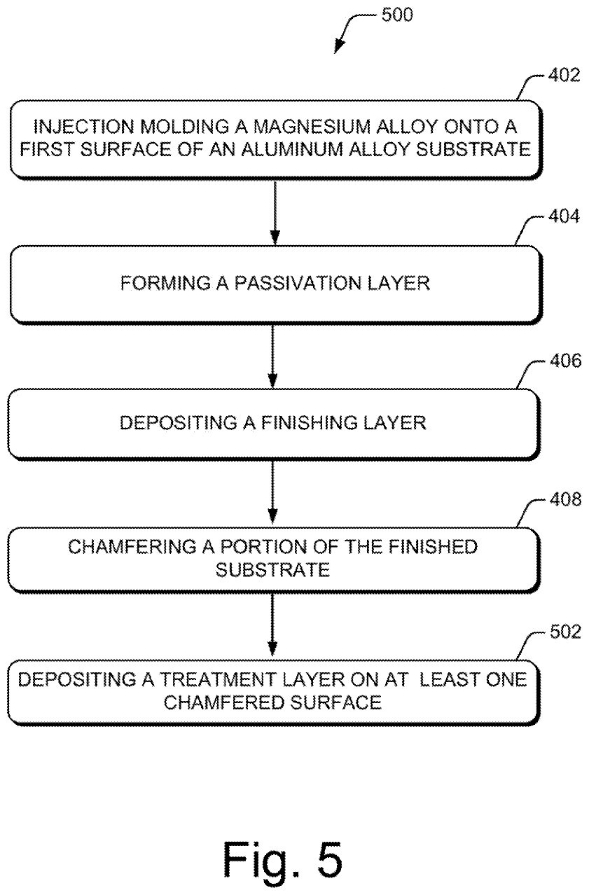

The chamfered surface 306 may be deposited with a treatment layer 308. As shown in FIG. 5, the method of forming electronic device covers 500 comprises depositing a treatment layer 308 onto at least one chamfered surface. In an example, the deposition 502, may be carried out by a process of electrophoretic deposition or anodization. In an example, the deposition 502, may result in a treatment layer having a thickness of about 5.0 μm to about 52.0 μm.

The chamfered device cover may be cleaned, dried, degreased, washed and polished prior to carrying out the deposition step 502 to obtain the treatment layer 308. In an example, the cleaning may be carried out in the presence of at least one aqueous alkaline compound such as sodium hydroxide. In an example, the polishing may be carried out in the presence of at least one acid selected from hydrochloric acid, nitric acid, phosphoric acid, or combinations thereof.

In an example, the deposition 502 may be carried out by electrophoretic deposition. In an example, the electrophoretic deposition may result in deposition of the treatment layer 308 having a thickness of from about 6.0 μm to about 40.0 μm. In another example, the electrophoretically deposited treatment layer 308 may have a thickness of from about 8.0 μm to about 30.0 μm. In another example, the electrophoretically deposited treatment layer 308 may have a thickness of from about 10.0 μm to about 25.0 μm. In another example, the electrophoretically deposited treatment layer 308 may have a thickness of about 18 μm.

The thickness of the treatment layer achieved may be directly related to the potential applied and time for the electrophoretic deposition. In an example, the electrophoretic deposition may be carried out by applying a potential in the range of from about 20 to about 150 V for a period in a range of from about 25 to about 120 seconds. In another example, the electrophoretic deposition may be carried out by applying a potential in the range of from about 50 to about 120 V for a period in a range of from about 50 to about 110 seconds. In another example, the electrophoretic deposition may be carried out by applying a potential of about 100 V for a period of about 70 seconds.

The treatment layer 308 deposited by electrophoretic deposition may comprise copolymers selected from polyacrylate copolymer, polyacrylic acid, epoxy, polyacrylamide-acrylic acid, and combinations thereof. In an example, the treatment layer 308 may comprise copolymers of polyacrylate. In another example, the treatment layer 308 may comprise copolymers of polyacrylamide-acrylic acid.

In an example, the deposition 502 may be carried out by anodization. In an example, the anodization may result in deposition of the treatment layer 308 having a thickness of from about 5.0 μm to about 12.0 μm. In another example, the anodized treatment layer 308 may have a thickness of from about 6.0 μm to about 13.0 μm. In another example, the anodized treatment layer 308 may have a thickness of from about 7.0 μm to about 12.0 μm. In another example, the anodized treatment layer 308 may have a thickness of about 10 μm. The chamfered device cover may be cleaned, dried, degreased, washed and polished prior to carrying out the anodization.

The thickness of the treatment layer deposited may be directly related to the potential applied and time for anodization. In an example, the anodization may be carried out by applying a potential in the range of from about 3 to about 20 V for a period in a range of from about 15 to about 50 minutes at a temperature in the range of from about 15° C. to about 25° C. In another example, the anodization may be carried out by applying a potential in the range of from about 5 to about 18 V for a period in a range of from about 20 to about 45 minutes at a temperature in the range of from about 17° C. to about 22° C. In another example, the anodization may be carried out by applying a potential of about 15 V for a period of about 40 minutes at a temperature of 20° C.

The device covers deposited with a treatment layer 308 by anodization, may be subsequently sealed and baked. In an example, the sealing may be carried out in the presence of a compound selected from aluminum fluoride, nickel fluoride, cerium fluoride, cerium acetate, aluminum acetate, nickel acetate, or combinations thereof. In an example, the sealing may be carried out in the presence of aluminum fluoride. In another example, the sealing may be carried out in the presence of nickel fluoride. In an example, the compound may be utilized in the form of an aqueous dispersion further comprising a surfactant having a strength of about 0.1% to about 2.0% with respect to the dispersion. In an example, the baking may be carried out at a temperature in the range of from about 60° C. to about 90° C. for a period in the range of about 15 seconds to about 180 seconds. In an example, the baking may be carried out at a temperature in the range of from about 62° C. to about 88° C. for a period in the range of about 30 seconds to about 60 seconds. In another example, the baking may be carried out at a temperature of 70° C. for a period of 45 seconds. In an example, the sealing layer thus obtained may have a thickness of about 1.0 μm to about 3.0 μm. In another example, the sealing layer may have a thickness of about 1.2 μm to about 2.8 μm.

In an example, the method 500 comprising depositing a treatment layer 308 on at least one chamfered surface 502, carried out by electrophoretic deposition or anodization, to obtain a device cover having different finish at the chamfered surface. The deposition process may be employed at selected chamfered surfaces to ensure a different finish for the chamfered surface, for instance, multicolored finish at selected chamfered surfaces. In an example, a treatment layer is deposited by electrophoretic deposition on a first chamfered surface and a treatment layer is deposited by anodization on a second chamfered surface. In an example, a treatment layer is deposited by a first electrophoretic deposition on a first chamfered surface and a treatment layer is deposited by a second electrophoretic deposition on a second chamfered surface. In an example, a treatment layer is deposited by first anodization on a first chamfered surface and a treatment layer is deposited by second anodization on a second chamfered surface.

### EXAMPLES

The description hereinafter describes prophetic examples, which are intended to illustrate examples of the present disclosure and not intended to be taken restrictively to imply any limitations on the scope of the present disclosure. Unless defined otherwise, all technical and scientific terms used herein have the same meaning as commonly understood to one of ordinary skill in the art to which this disclosure belongs. It is to be understood that this disclosure is not limited to the particular methods and experimental conditions described, as such methods and conditions may vary depending on the process and inputs used as will be easily understood by a person skilled in the art.

### Prophetic Example 1

A magnesium alloy (AZ91D) is injection-molded on a surface of an injection-molded aluminum alloy substrate (A380). Said magnesium alloy has a thickness of 0.7 mm, whereas the aluminum alloy has substrate has a thickness of 0.7 mm. The injection-molding of magnesium alloy is carried out at a temperature of about 550° C. by thixo-molding.

After injection-molding, the dual injection-molded metal substrate is subjected to passivation by micro-arc oxidation at a voltage of 350 V to obtain a thickness of about 12 μm. Further, a finishing layer having a thickness of about 44 μm is deposited by spray coating.

The spray coating is carried out in a step-wise manner. Herein, the polyurethane primer is first deposited by spray coating followed by heat treatment at 70° C. for a period of 25 minutes. Said primer has a thickness of about 12 μm. This is followed by the deposition of a base coat made of carbon-black containing polyurethane. The deposition is carried out by spray coating followed by heat treatment at 70° C. for a period of 25 minutes. The base coat has a thickness of 15 μm. Finally, a top coat made of polyacrylic acid is applied by spray coating followed by UV treatment at 950 mJ/cm² for a period of 20 seconds. The top coat has a thickness of 17 μm.

After deposition, the substrate is subjected to chamfering using a CNC laser machine. The chamfering is done by using a laser power of about 100 W and an engraving speed of about 450 mm/minute.

### Prophetic Example 2

A magnesium alloy (AZ91D) is injection-molded on a surface of an injection-molded aluminum alloy substrate (A380). Said magnesium alloy has a thickness of 0.7 mm, whereas the aluminum alloy substrate has a thickness of 0.7 mm. The injection-molding of magnesium alloy is carried out at a temperature of about 550° C. by thixo-molding.

After injection-molding, the dual injection-molded metal substrate is subjected to passivation by dip-coating the substrate in an aqueous solution containing molybdate salt (12 wt. %) for 60 seconds to obtain a thickness of about 3 μm. Further, a finishing layer having a thickness of about 44 μm is deposited by spray coating.

The spray coating is carried out in a step-wise manner. Herein, the polyurethane primer is first deposited by spray coating followed by heat treatment at 70° C. for a period of 25 minutes. Said primer has a thickness of about 12 μm. This is followed by the deposition of a base coat made of carbon-black containing polyurethane. The deposition is carried out by spray coating followed by heat treatment at 70° C. for a period of 25 minutes. The base coat has a thickness of 15 μm. Finally, a top coat made of polyacrylic acid is applied by spray coating followed by UV treatment at 950 mJ/cm² for a period of 20 seconds. The top coat has a thickness of 17 μm.

After deposition, the substrate is subjected to chamfering using a CNC laser machine. The chamfering is done by using a laser power of about 100 W and an engraving speed of about 450 mm/minute.

### Prophetic Example 3

A magnesium alloy (AZ91D) is injection-molded on a surface of an injection-molded aluminum alloy substrate (A380). Said magnesium alloy has a thickness of 0.7 mm, whereas the aluminum alloy has substrate has a thickness of 0.7 mm. The injection-molding of magnesium alloy is carried out at a temperature of about 550° C. by thixo-molding.

After injection-molding, the dual injection-molded metal substrate is subjected to passivation by micro-arc oxidation at a voltage of 350 V to obtain a thickness of about 12 μm. Further, a finishing layer having a thickness of about 20 μm is deposited by electrophoretic deposition.

The electrophoretic deposition is carried out at a potential of 115 V for 80 seconds.

After deposition, the substrate is subjected to chamfering using a CNC laser machine. The chamfering is done by using a laser power of about 100 W and an engraving speed of about 450 mm/minute.

### Prophetic Example 4

The device cover obtained by the method mentioned above under prophetic example 1 was further subjected to electrophoretic deposition under a potential of 80 V for 70 seconds. The treatment layer, thus deposited contains polyacrylate and has a thickness of about 12 μm.

### Prophetic Example 5

The device cover obtained by the method mentioned above under prophetic example 1 was further subjected to anodization under a potential of 14 V for 35 minutes. The treatment layer, thus deposited contains an oxide layer and has a thickness of about 8 μm.

Although examples for the present disclosure have been described in a language specific to structural features and/or methods, it is to be understood that the appended claims are not limited to the specific features or methods described herein. Rather, the specific features and methods are disclosed and explained as examples of the present disclosure.

We claim:

1. A dual injection-molded metal substrate comprising:
an injection-molded aluminum alloy substrate; and
an injection-molded magnesium alloy layer on a portion of a first surface of the aluminum alloy substrate.

2. The dual injection-molded metal substrate as claimed in claim 1, wherein the aluminum alloy substrate has a thickness of from about 0.3 mm to about 2.0 mm and the magnesium alloy layer has a thickness from about 0.3 mm to about 2.0 mm.

3. The dual injection-molded metal substrate as claimed in claim 1, wherein the magnesium alloy is injection-molded onto the alloy substrate at a temperature of from about 350° C. to about 850° C.

4. The dual injection-molded metal substrate as claimed in claim 1, wherein the aluminum alloy is selected from AL5005, A380, AL5050, AL5052, AL5154, AL5252, AL6061, AL6063, AL6151, AL6162, AL6205, AL7072, AL7075, AL7475, AL1100, AL575, A413, ADC12, or combinations thereof.

5. The dual injection-molded metal substrate as claimed in claim 1, wherein the magnesium alloy is selected from AZ31B, AZ91D, AZ61, AZ60, AZ80, AM60, LZ91, LZ141, LZ142, ALZ691, or combinations thereof.

6. The dual injection-molded metal substrate as claimed in claim 1, wherein the magnesium alloy layer on a portion of a first surface of the aluminum alloy substrate provides a patterned finish.

7. A device cover for an electronic device, the device cover comprising:
an injection-molded aluminum alloy substrate;
a magnesium alloy layer injection-molded on a first surface of the aluminum alloy substrate;
a passivation layer formed on the substrate;
a finishing layer deposited on the passivation layer; and
a treatment layer deposited on at least one chamfered surface.

8. The device cover as claimed in claim 7, wherein:
the injection-molded aluminum alloy substrate is selected from AL5005, A380, AL5050, AL5052, AL5154, AL5252, AL6061, AL6063, AL6151, AL6162, AL6205, AL7072, AL7075, AL7475, AL1100, AL575, A413, ADC12, or combinations thereof and has a thickness from about 0.3 mm to about 2.0 mm.

9. The device cover as claimed in claim 7, wherein:
the magnesium alloy layer is selected from AZ31B, AZ91D, AZ61, AZ60, AZ80, AM60, LZ91, LZ141, LZ142, ALZ691, or combinations thereof and has a thickness of from about 0.3 mm to about 2.0 mm.

10. The device cover as claimed in claim 7, wherein:
the passivation layer has a thickness of from about 1.0 μm to about 15.0 μm; and
the finishing layer has a thickness of from about 15.0 μm to about 65.0 μm.

11. A method of forming an electronic device cover, the method comprising:
injection-molding a magnesium alloy layer onto an aluminum alloy substrate at a temperature in a range of from about 350° C. to about 850° C.;
forming a passivation layer onto the substrate, the passivation layer having a thickness in a range of from about 1.0 μm to about 15.0 μm;
depositing a finishing layer onto the passivation layer to obtain a finished substrate; and
chamfering a portion of the finished substrate to obtain the device cover.

12. The method as claimed in claim 11, wherein forming a passivation layer is carried out by a process of oxidation or coating.

13. The method as claimed in claim 11, wherein depositing a finishing layer is carried out by electrophoretic deposition or spray coating and said layer has a thickness of from about 15.0 μm to about 65.0 μm.

14. The method as claimed in claim 13, wherein the finishing layer comprises:
a primer having a thickness of from about 5.0 μm to about 20.0 μm;
a base coat having a thickness of from about 10.0 μm to about 20.0 μm; and
a top coat having a thickness of from about 10.0 μm to about 25.0 μm.

15. The method as claimed in claim 11, the method comprising:
depositing a treatment layer onto at least one chamfered surface, carried out by electrophoretic deposition or anodization, to obtain a device cover having different finish at the chamfered surface.
